(19) United States
(12) Patent Application Publication
(10) Pub. No.: US 2026/0197997 A1
(43) Pub. Date: Jul. 9, 2026

(54) SEMICONDUCTOR STRUCTURE WITH TSVS

(71) Applicant: Powerchip Semiconductor Manufacturing Corporation, HSINCHU (TW)

(72) Inventors: Shou-Zen Chang, HSINCHU (TW); Yen-Jhih Huang, HSINCHU (TW); Chun-Lin Lu, HSINCHU (TW)

(73) Assignee: Powerchip Semiconductor Manufacturing Corporation, HSINCHU (TW)

(21) Appl. No.: 19/035,985

(22) Filed: Jan. 24, 2025

(30) Foreign Application Priority Data
Jan. 7, 2025 (TW) 114100553

(51) Int. Cl. H10B 12/00; H01L 23/48

(52) U.S. Cl. CPC H10B 12/50; H10B 12/315; H10W 20/20

(57) ABSTRACT

A semiconductor device includes: a substrate including a first face, on which an active area is formed, and a second face opposite to the first face; an electronic element formed on the active area; a front wiring structure disposed on the first face of the substrate and connected to the electronic element; a trench capacitor filling at least a portion of a back trench extending into the substrate from the second face of the substrate; a back wiring structure disposed on the second face of the substrate and connected to the trench capacitor; and a through-via extending through the substrate to electrically connect the electronic element and the back wiring structure to each other.

### BACKGROUND OF THE INVENTION

### 1. Field of the Invention

The present invention generally relates to a semiconductor structure having through-silicon vias (TSVs), and more specifically, to a semiconductor structure with through silicon interconnects overlapping other vertical interconnects (vias).

### 2. Description of the Prior Art

A through-silicon via (TSV) is a vertical interconnect that runs through silicon wafer(s) or chip(s), distinguishing it from traditional vertical interconnect accesses (vias), which typically connect different metal interconnect layers on a substrate. The TSV extends through the entire substrate or wafer to achieve chip-to-chip, chip-to-wafer, and/or wafer-to-wafer circuit interconnection. By utilizing 3D interconnection technology with direct through-holes in the silicon wafer to replace conventional wire bonding, TSV technology continue to push the boundaries of Moore's Law, enabling the interconnection and single packaging of multiple ICs in a three-dimensional stack, and facilitates the integration of logic, memory, and analog devices operating in a manner similarly to a system-on-chip (SoC). As the interconnect lines are situated between chips, the internal connection paths are shortened, resulting in faster transmission speed, reduced noise, and overall performance enhancement. TSV technology also meets the demands for high-density integration and addresses the process and packaging challenges commonly faced in SoC development.

Depending on the manufacturing processes, the methods for fabricating through-silicon interconnects can be classified into three categories: via-first, via-middle, and via-last. These processes occur respectively during the semiconductor front-end-of-line (FEOL) process, after the FEOL process but before the semiconductor back-end-of-line (BEOL) process, and after the BEOL process. Specifically, for the via-last TSV process, since the TSV is fabricated after the BEOL interconnects are already formed, the prevailing industry practice is to design the TSVs in such a way that they do not overlap with the existing BEOL metal interconnects (ex. vias) in the vertical direction in layout design.

More specifically, please refer to FIGS. 1 and 2, which illustrate respectively a schematic layout diagram and a schematic cross-sectional view of a through-silicon interconnect (TSV) and metal interconnects according to prior art. As depicted in the figures, in terms of the hierarchical structure of circuit connections, component 10 represents the TSV, component 20 denotes a metal interconnect layer directly connected to the TSV 10, components 22 represents vias directly connecting to the metal interconnect layer 20, and component 30 refers to a BEOL metal interconnect layer directly connected to the vias 22. From the perspective of semiconductor process, the aforementioned BEOL metal interconnect layer 30 corresponds to a metal circuit formed during the BEOL process, such as the well-known first metal layer (M1), which may then connect to upper BEOL metal interconnects like M2, V2, M3, V3, and so on. The metal interconnect layer 20 and via 22 are part of the metal circuits formed in the semiconductor middle-end-of-line (MEOL) process, serving to connect the aforementioned BEOL metal interconnects to the active areas of the substrate, effectively acting as a transition level between semiconductor circuits and metal interconnects. In some logic processes, the metal interconnect layer 20 is referred to as the zeroth metal layer (M0), while the via 22 is known as the zeroth via (V0). In memory process, the capacitor structure is typically positioned at the MEOL level. In other aspect, for the via-last TSV 10, the metal interconnect layer 20 and vias 22 are formed first, after which the TSV 10 then penetrates through the substrate and/or the dielectric layer(s) at the FEOL level and connects to the pre-existing metal interconnect layer 20.

Referring again to FIGS. 1 and 2, it is evident from the figures that, in conventional technology, the TSV 10 is deliberately designed to avoid overlapping with the vias 22 at the MEOL level in the direction vertical to the substrate. With such a design, the vias 22 must be positioned in a layout space separate from the TSV 10. Since both the vias 22 and the TSV 10 are directly connected to the metal interconnect layer 20 in the vertical direction, the layout of the metal interconnect layer 20 must be expanded to cover and exceed the area of TSV 10. The layout plane between the metal interconnect layer 20 and the TSV 10 is the location where the vias 22 are placed. This design inevitably increases the layout area required for the metal interconnect layer 20. In addition, because the current path from the TSV 10 through the metal interconnect layer 20 to the vias 22 is longer, the overall resistance of the circuit is also higher. Moreover, since the BEOL metal interconnect layer 30 is directly connected to the vias 22 in the vertical direction, its layout pattern is constrained by the placement of the vias 22. Consequently, under the condition that the TSV 10 and vias 22 do not overlap in the vertical direction, the layout pattern of the BEOL interconnect layer 30 is bound to cover and exceed the area of TSV 10, much like the metal interconnect layer 20. This added design complexity increases the difficulty of routing the BEOL metal circuit.

### SUMMARY OF THE INVENTION

In light of the various limitations and drawbacks associated with the conventional approaches mentioned above, the present invention hereby introduces a novel semiconductor structure incorporating through-silicon via (TSVs), which is characterized by the ability of the TSVs to vertically overlap with the vias at the semiconductor MEOL level, thereby reducing the necessary area and resistance of the metal interconnect layer and make the routing design of the BEOL metal circuit more flexible.

The objective of the present invention is to provide a semiconductor structure with TSVs, including: a substrate, with a cell region, a peripheral region and a TSV region defined on a frontside, and a plurality of active areas are formed in the substrate; a pre-metal dielectric layer on the frontside of the substrate; multiple storage node contacts in the pre-metal dielectric layer on the cell region and directly connected to the active areas; multiple contacts in the pre-metal dielectric layer on the peripheral region and directly connected to the active areas; a peripheral metal interconnect layer on the pre-metal dielectric layer and directly connected to the contacts on the peripheral region; an interlayer dielectric layer on the pre-metal dielectric layer and the peripheral metal interconnect layer; multiple capacitors in the interlayer dielectric layer on the cell region and connected to the storage node contact; a BEOL metal interconnect on the interlayer dielectric layer; multiple vias in the interlayer dielectric layer and directly connecting the peripheral metal interconnect layer and the BEOL metal interconnect; and a TSV, directly connected to the peripheral metal interconnect layer in the TSV region from a backside of the substrate through the substrate and the pre-metal dielectric layer, wherein the TSV overlaps the vias in a direction vertical to the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 presents a schematic layout diagram of a through-silicon via (TSV) and metal interconnects in prior art;

FIG. 2 presents a schematic cross-sectional view of a TSV and metal interconnects in prior art;

FIG. 3 presents a schematic layout diagram of a TSV and metal interconnects in accordance with an embodiment of the present invention;

FIG. 4 presents a schematic cross-sectional view of a TSV and metal interconnects in accordance with an embodiment of the present invention;

FIG. 5 presents a schematic cross-sectional view of a dynamic random access memory (DRAM) in accordance with an embodiment of the present invention;

FIG. 6 presents a schematic cross-sectional view of a dynamic random access memory (DRAM) in accordance with an embodiment of the present invention; and

FIG. 7 presents a schematic cross-sectional view of a dynamic random access memory (DRAM) in accordance with an embodiment of the present invention.

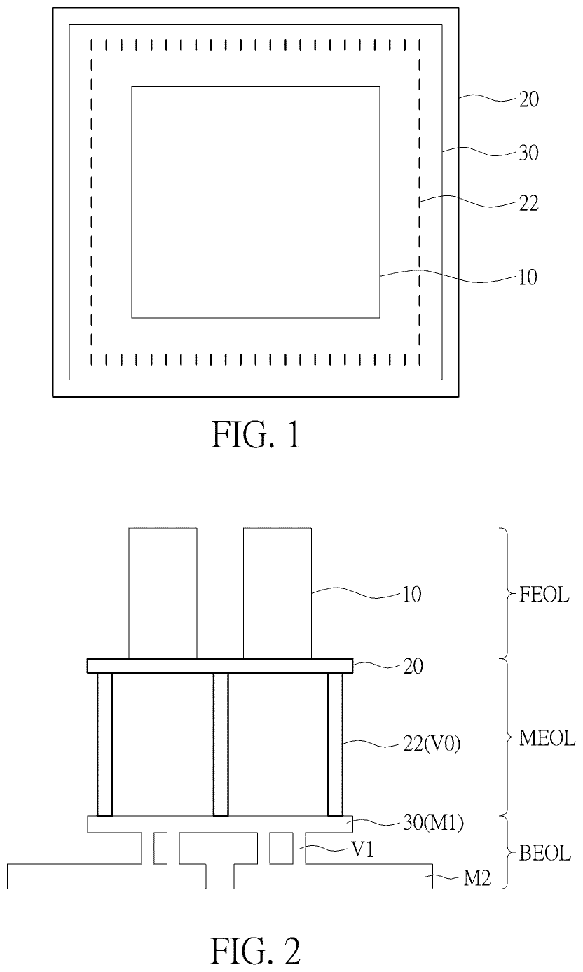

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

In addition, spatially relative terms (e.g., “beneath,” “below,” “lower,” “above,” “upper” and the like) may be used herein for ease of description to describe one element or a relationship between a feature and another element or feature as illustrated in the figures.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon (Si), germanium (Ge), gallium arsenide (GaAs), indium phosphide (InP), etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

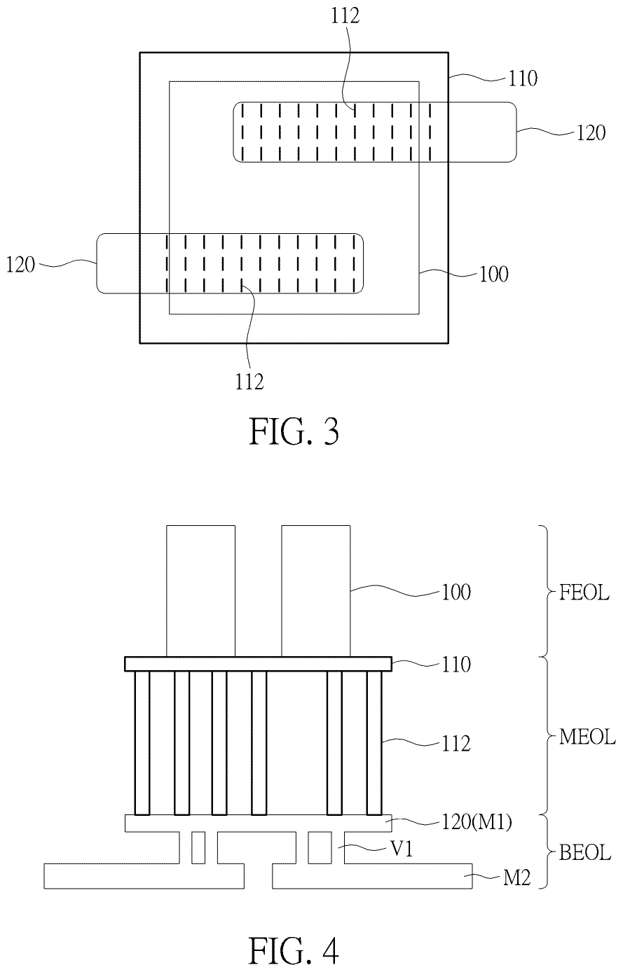

First, please refer to FIGS. 3 and 4 simultaneously, which illustrate respectively a schematic layout diagram and a schematic cross-sectional view of a through-silicon via (TSV) and metal interconnects according to an embodiment of the present invention. As depicted in the figures, in terms of the hierarchical structure of circuit connections, component 100 represents the TSV, component 110 denotes a metal interconnect layer directly connected to the TSV 100, components 112 represent vias directly connected to the metal interconnect layer 110, and component 120 refer to a BEOL metal interconnect layer directly connected to the vias 112. From a perspective of semiconductor process, the aforementioned BEOL metal interconnect layer 120 corresponds to a metal circuit formed during the BEOL process, such as the well-known first metal layer M1, which is connected to upper BEOL metal interconnects, such as the second metal layer M2, the second via V2, the third metal layer M3, the third via V3, etc., through the first via V1. In the figures, only M1, V1, and M2 are shown to represent the entirety of the BEOL metal interconnects. In this embodiment, the metal interconnect layer 110 and via 112 are metal circuits produced during the semiconductor MEOL process, which serve to connect the aforementioned BEOL metal interconnects to the active areas of the substrate (not shown). These components belong to the transition level between semiconductor-based circuits and metal-based interconnects. In some logic processes, the metal interconnect layer 110 may be referred to as the zeroth metal layer (MO), and the via 112 may be referred to as the zeroth via (VO). In memory process, capacitor structures and bit lines are typically positioned at the MEOL level. In other aspect, for the via-last TSV 100, the metal interconnect layer 110 and the via 112 are formed first, followed by the penetration of the TSV 100 through the substrate and/or dielectric layer at the semiconductor FEOL level, where it is connected to the pre-formed metal interconnect layer 110.

Referring again to FIGS. 3 and 4, in the embodiment of the present invention, and in contrast to conventional skill, the TSV 100 is designed to overlap with the vias 112 at the MEOL level in the direction vertical to the substrate. As illustrated in the figures, some of the vias 112 are positioned within the plane layout of the TSV 100, while others are located outside the layout of TSV 100 but still within the plane layout of the metal interconnect layer 110. This design offers several advantages. Notably, the layout pattern of the BEOL metal interconnect layer 120, which in conventional designs would be constrained by the layout position of the vias 112, is now much more flexible and unrestricted. The placement of vias 112 allows the layout design to be more adaptable, eliminating the need for the BEOL metal interconnect layer to cover and exceed the layout of TSV 100. This flexibility significantly reduces the complexity of routing BEOL metal circuits. Moreover, because the vias 112 no longer need to be confined to the planar layout space of the metal interconnect layer 110 outside the TSV 100, the area of the metal interconnect layer 110 can be reduced, facilitating the miniaturization of the overall circuit. Additionally, the current path from the TSV 100 to the vias 112 through the metal interconnect layer 110 is also shortened, resulting in lower overall resistance in the circuit. These design enhancements demonstrate the numerous advantages of the semiconductor structure proposed in the present invention.

Having presented the schematic layout diagram and cross-sectional view of the aforementioned TSV and metal interconnects, the following embodiment will use a dynamic random access memory (DRAM) as an example to demonstrate the application of the semiconductor structure with TSV of the present invention in memory architecture.

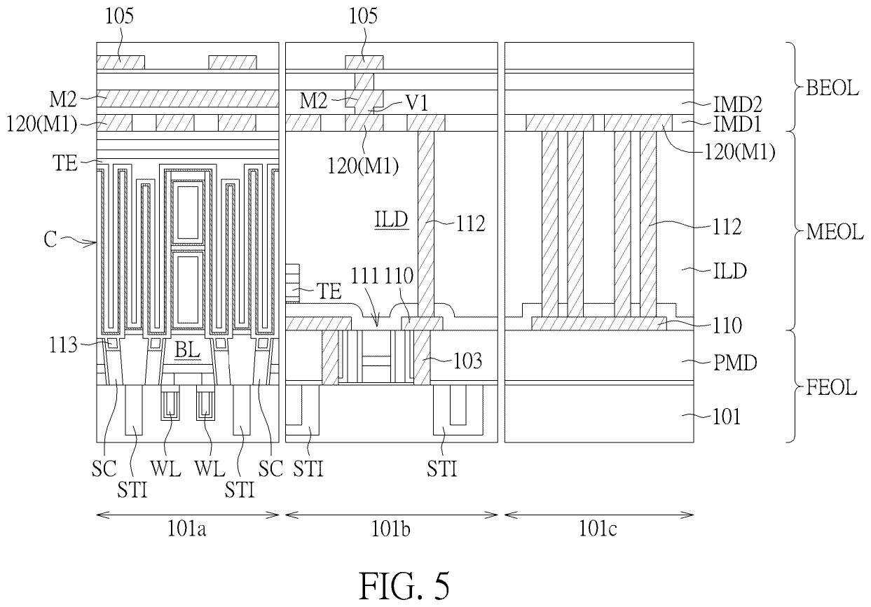

Please refer now to FIG. 5, which illustrates a schematic cross-sectional view of a DRAM structure according to an embodiment of the present invention. In this embodiment, the memory cells and various necessary components of the DRAM are fabricated on a substrate 101. The substrate 101 may be a silicon wafer, with distinct regions defined thereon, including a cell region 101a, a peripheral region 101b and a TSV region 101c. Shallow trench isolations STI are provided to separate multiple active areas exposed from the surface of the substrate 101. Additionally, dopants can be introduced into each active area through a doping process to form various doped regions, such as sources, drains, wells (not shown). In this embodiment, components such as word lines WL, bit lines BL, and storage node contacts SC are formed on the cell region 101a, wherein the word lines WL are buried within the substrate 101, and they can switch the channels in corresponding row during read and write operations, enabling the selection of a specific cell row. The bit line BL and the storage node contact SC are positioned on the substrate 101 and connected to the corresponding active areas below. Each storage node contact SC is further connected to its corresponding capacitor C above. During read and write operations, the bit line BL serves as the primary signal channel. When the corresponding cell row is selected and turned on by the word line WL, the data stored in the capacitor C is transmitted to the bit line BL through the storage node contact for reading. Conversely, data from an external circuit can be written from the bit line BL through the storage node contact SC into capacitor C for storage.

Continuing with reference to FIG. 5, the peripheral region 101b is where the peripheral devices of the DRAM are situated, which may include various devices such as row/column decoders, column amplifiers, row selectors and refresh controllers, data buffers, timing controllers, power management modules, error correction circuits. These components are responsible for processing both the read signal and the signal to be written, and are represented by a single device 111 in the figure. Within the peripheral region 101b, a contact 103 is placed to connect the active area of the substrate 101 to the upper peripheral metal interconnect layer 110, which is then connected to a metal layer 120 in the upper BEOL metal interconnects, such as the first metal layer (M1), through a via 112. It is important to note that, in the present invention, the term “contact” refers specifically to the vertical interconnect that connects the semiconductor-based active area to the metal-based interconnect layer, while the term “via” refers specifically to the vertical interconnect connecting two metal-based interconnect layers. In this embodiment, a pre-metal dielectric layer (PMD), such as a silicon oxide layer, is formed over the substrate 101. The aforementioned various devices 111 are generally formed within the pre-metal dielectric layer PMD, and the contact 103 is also formed within the pre-metal dielectric layer PMD to establish connection between the active area in the substrate 101 and the peripheral metal interconnect layer 110 on the surface of the pre-metal dielectric layer PMD. Taking the DRAM process as an example, all of these components in the pre-metal dielectric layer PMD, including the word lines WL, bit lines BL, storage node contacts SC, active areas, various devices 111, contacts 103, etc., are in the semiconductor FEOL level.

Continuing with reference to FIG. 5, in the embodiment, a thick dielectric layer, such as an interlayer dielectric layer (ILD), is deposited on the pre-metal dielectric layer PMD, using materials like silicon oxide or low-k materials. In terms of the DRAM process, the interlayer dielectric layer ILD is considered part of the semiconductor MEOL level. This layer primarily provides space for the capacitor structure and serves as an interconnection level for the transition between the FEOL level and the BEOL level. Among them, capacitors C are formed within the interlayer dielectric layer ILD on the cell region 101a, where they are connected to the corresponding storage node contact SC beneath. Additionally, a via 112 is provided in the interlayer dielectric layer ILD within the peripheral region 101b. This via penetrates the interlayer dielectric layer ILD and establishes a connection between the peripheral metal interconnect layer 110 below and the first metal layer (M1) 120 above, thereby enabling the devices 111 in the peripheral region 101b to be connected to the BEOL metal circuit. In the present invention, the above-mentioned peripheral metal interconnect layer 110 and via 112 can be considered as the zeroth metal layer (M0) and the zeroth via (V0) in the BEOL metal interconnects. Regarding the material, the contact 103, peripheral metal interconnect layer 110 and via 112 are both formed of tungsten (W). It is also noteworthy that in certain embodiments, the peripheral metal interconnect layer 110 in the peripheral region 101b and the contact pad 113 on the storage node contact SC may belong to the same metal layer and be fabricated using the same process. Furthermore, the device 111 in the peripheral region 101b may be an extension of the bit line BL and may be formed in the same process as the bit line BL. The capacitors C may also include parts extending into the peripheral region 101b, such as the upper electrode TE of the capacitors C in the figure, which extends into the peripheral region 101b and is positioned directly above the peripheral metal interconnect layer 110.

Referring again to FIG. 5, in this embodiment, due to the need for TSV placement, no doped regions, shallow trench isolations or functional devices are formed in the substrate 101 and the pre-metal dielectric layer PMD in the TSV region 101c. The TSV is intended to be connected from the backside of the substrate 101 to the peripheral metal interconnection layer 110 in the MEOL level after the completion of the BEOL process, following an approach of via-last process. Similar to the peripheral region 101b, a via (V0) 112 is formed within the interlayer dielectric layer ILD in the TSV region 101c. This via penetrates the interlayer dielectric layer ILD and establishes a connection between the lower peripheral metal interconnect layer (M0) 110 and the first metal layer (M1) 120 in the upper semiconductor BEOL level, allowing the subsequently connected TSV to be further connected to the BEOL metal circuit. In the semiconductor BEOL level, the BEOL metal interconnects is composed of multiple metal layers, such as the first metal layer M1, the second metal layer M2, M3, and so on, with corresponding vias (V1, V2, V3, etc.) connecting therebetween. These metal layers and vias are located within the corresponding inter-metal dielectric layers (IMD1, IMD2, IMD3, etc.), typically made from materials such as silicon oxide or phosphorus-doped tetraethoxysilane (P-TEOS). In the DRAM process, the aforementioned BEOL metal interconnects are primarily made of copper (Cu), in contrast to the metal interconnects in MEOL level, which are formed of tungsten (W). Since tungsten has a significantly higher resistance than copper, the current path in the MEOL level can be shortened to effectively reduce the overall resistance of the semiconductor structure. Additionally, in this embodiment, contact pads 105 are formed in the outermost layer of the BEOL level, providing a means for the BEOL metal circuits to connect to external circuits. The contact pads 105 are typically made from aluminum (Al), known for its simple manufacturing process as well as its excellent thermal stability and oxidation resistance.

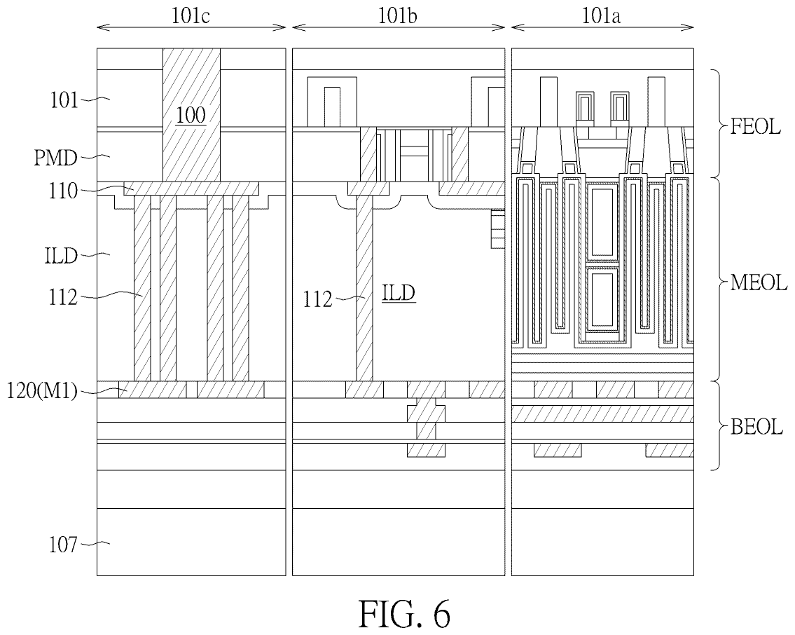

Please refer now to FIG. 6. After completing the BEOL process as described earlier, the substrate 101 is flipped over, so that the frontside faces down and is bonded to a carrier substrate 107 using a technique such as thermal compression bonding. This sets the stage for the subsequent backside processing. In this embodiment, the TSV 100 extends from the backside of the substrate 101 through the substrate 101 and the pre-metal dielectric layer PMD, and ultimately connecting to the peripheral metal interconnect layer 110 in the MEOL level. In an embodiment, the manufacturing process for fabricating the TSV 100 can be summarized as follows: First, forming a through-silicon hole through the substrate 101 and the pre-metal dielectric layer PMD using a photolithography process, such as laser or deep reactive ion etching (DRIE), until the peripheral metal interconnect layer 110 is exposed; After the through-silicon hole is formed, process like sub-atmospheric pressure chemical vapor deposition (SA-CVD), physical vapor deposition (PVD) or atomic layer deposition (ALD) is performed to deposit a barrier layer and a seed layer on the hole's surface. Next, electroplated copper is used to fill the through-silicon hole. Lastly, the metal layer outside the through-silicon hole is removed through a chemical mechanical planarization (CMP), leaving the TSV 100 in place, which connects the peripheral metal interconnect layer 110 and is exposed on the backside of the substrate 101. As shown in the figure, in the present invention, the TSV 100 is designed to overlap with part of the vias 112 (i.e., V0) in the MEOL level along the vertical direction. This means the position of vias 112 is no longer constrained by the layout position of the TSV 100. This design significantly enhances the flexibility of the BEOL metal interconnect layer 120 (such as the first metal layer, M1), making it easier to manage the routing of the BEOL metal circuits. Additionally, the area required for the peripheral metal interconnect layer 110 (i.e., the zeroth metal layer M0) is reduced, which in turn aids in miniaturizing the circuit. Furthermore, the shortening of the current path between the TSV 100 and vias 112 help reduce the overall resistance of the circuit. These advantages demonstrate the effectiveness of the structural design proposed in the present invention.

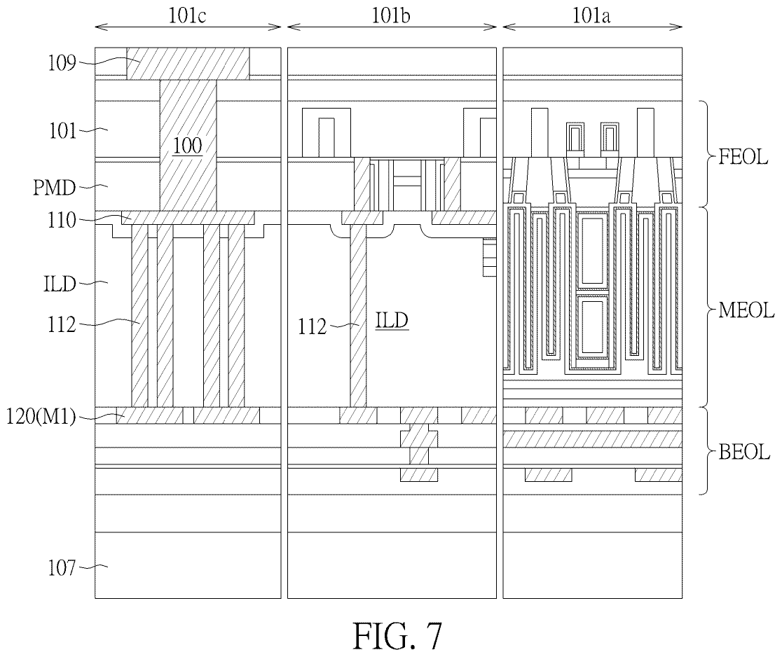

Finally, please refer to FIG. 7. Once the TSV 100 is formed, a redistribution layer (RDL) 109 is formed on the backside of the substrate, directly connecting to the TSV 100. In this embodiment, the redistribution layer 109 serves to reorganize and distribute the I/O contacts (e.g., solder balls or bonding pads) on both the surface of the TSV 100 and the substrate 101. This ensures that the I/O contacts are optimally positioned for connection to external circuits. For instance, in this embodiment, the redistribution layer 109 converts the vertical signals from the TSV 100 into horizontal signals, directing them to the external pads and/or solder balls of the chip. The present invention utilizes the TSV 100 to enable vertical interconnection between wafers or chips, facilitating the integration and connection of circuit from multiple vertically stacked DRAM dies into a single circuit. This arrangement supports high-density and high-performance electrical connection, making it ideal for advanced 2.5D or 3D IC packaging.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure with TSVs, comprising:
a substrate, with a cell region, a peripheral region and a TSV region defined on a frontside, and a plurality of active areas are formed in said substrate;
a pre-metal dielectric layer on said frontside of said substrate;
multiple storage node contacts in said pre-metal dielectric layer on said cell region and directly connected to said active areas;
multiple contacts in said pre-metal dielectric layer on said peripheral region and directly connected to said active areas;
a peripheral metal interconnect layer on said pre-metal dielectric layer and directly connected to said contacts on said peripheral region;
an interlayer dielectric layer on said pre-metal dielectric layer and said peripheral metal interconnect layer;
multiple capacitors in said interlayer dielectric layer on said cell region and connected to said storage node contact;
a BEOL metal interconnect on said interlayer dielectric layer;
multiple vias in said interlayer dielectric layer and directly connecting said peripheral metal interconnect layer and said BEOL metal interconnect; and
a TSV, directly connected to said peripheral metal interconnect layer in said TSV region from a backside of said substrate through said substrate and said pre-metal dielectric layer, wherein said TSV overlaps said vias in a direction vertical to said substrate.

2. The semiconductor structure with TSVs of claim 1, wherein said peripheral metal interconnect layer in said cell region is a storage node contact pad directly connected to said storage node contacts.

3. The semiconductor structure with TSVs of claim 1, wherein said capacitors have an upper electrode extending to said peripheral region and positioned directly above said peripheral metal interconnect layer.

4. The semiconductor structure with TSVs of claim 1, further comprising a plurality of bit lines in said pre-metal dielectric layer on said cell region.

5. The semiconductor structure with TSVs of claim 1, further comprising a redistribution layer on said backside of said substrate and directly connected to said TSVs.

6. The semiconductor structure with TSVs of claim 1, further comprising a plurality of peripheral devices in said pre-metal dielectric layer on said peripheral region.

7. The semiconductor structure with TSVs of claim 1, wherein said peripheral metal interconnect layer and said vias are made of a first metal material, and said BEOL metal interconnect and said TSV is made of a second metal material, and said first metal material is different from said second metal material.

8. The semiconductor structure with TSVs of claim 7, wherein said first metal material comprises tungsten, and said second metal material comprises copper.
